(19) United States
(12) Patent Application Publication
(10) Pub. No.: US 2009/0321110 A1
(43) Pub. Date: Dec. 31, 2009

(54) MICRO ELECTRO-MECHANICAL SYSTEM

(75) Inventors: YI-MOU HUANG, Tu-Cheng (TW); JEN-TSORNG CHANG, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/255,545

(22) Filed: Oct. 21, 2008

(30) Foreign Application Priority Data
Jun. 26, 2008 (CN) 200810302323.0

(51) Int. Cl. H05K 1/14

(52) U.S. Cl. 174/254; 174/261

(57) ABSTRACT

In one embodiment, a MEMS includes a MEMS chip package, a first printed circuit board (PCB), an anisotropic conductive layer, a second PCB and at least one electrical wire. The MEMS chip package includes an exposed connecting portion, and at least one metallic pad formed on the exposed connecting portion. The first PCB is laminated on the connecting portion. The first PCB includes at least one first connecting metallic pad and at least one second connecting metallic pad. The first connecting metallic pad is electrically connected to a corresponding second connecting metallic pad. The anisotropic conductive layer is sandwiched between the metallic pads of the MEMS chip package and the first connecting metallic pads of the first PCB. The metallic pad of the MEMS chip package is electrically connected to the respective first connecting metallic pad of the PCB via the anisotropic conductive layer. One end of each electrical wire being bonded to a respective second connecting metallic pad and the other end being bonded to the second PCB. The MEMS actuator can be easily connected to driver circuit via tiny copper wires.

### BACKGROUND

1. Technical Field

The present invention generally relates to micro-electro-mechanical system (MEMS), and particularly, relates to highly compact MEMS.

2. Discussion of Related Art

Micro-electro-mechanical systems (MEMS) are widely employed in various kinds of micro-electronics devices due to its attractive properties of miniaturization, versatile and highly integrated. Typical application of MEMS system includes micro-sensors and micro-actuators. Generally, micro-actuators are configured for driving movable members (e.g. lens group in a lens module) in micro-electronics devices to move according to controlling signals provided by a driver circuit (i.e. an integrated circuit mounted on a printed circuit board). Thus, the micro-actuators are desired to be electrically connected to the driver circuit.

To reduce space occupied by the micro-electronics devices, the printed circuit boards are usually mounted on a side of the micro-electronics devices. That is, the micro-actuator is perpendicular to the printed circuit board. Thus, a flexible conducting member capable of freely bending at least 90° is needed for electrically connecting the micro-actuator to the driver circuit. Tiny copper wires have adequate flexibility and are proposed as a suitable candidate for such an application. However, when MEMS actuators are made into micrometer-scale, the conventional copper wires are not satisfactory for these circumstances. Firstly, a space performing copper wire bonding on a surface of the MEMS actuator is limited; secondly, copper wires are undesirable to be directly bonded with aluminum pads formed on the surface of the MEMS actuator.

Therefore, there is a desire to provide a MEMS and a method of electrically connecting micro-actuators to driver circuits.

### SUMMARY

In one exemplary embodiment, MEMS includes a MEMS chip package, a first printed circuit board (PCB), an anisotropic conductive layer, a second PCB and at least one electrical wire. The MEMS chip package includes an exposed connecting portion, and at least one metallic pad formed on the exposed connecting portion. The first PCB is laminated on the connecting portion. The first PCB includes at least one first connecting metallic pad and at least one second connecting metallic pad. The first connecting metallic pad is electrically connected to a corresponding second connecting metallic pad. The anisotropic conductive layer is sandwiched between the metallic pads of the MEMS chip package and the first connecting metallic pads of the first PCB. The metallic pad of the MEMS chip package is electrically connected to the respective first connecting metallic pad of the PCB via the anisotropic conductive layer. One end of each electrical wire being bonded to a respective second connecting metallic pad and the other end being bonded to the second PCB.

This and other features and advantages of the present invention as well as the preferred embodiments thereof and a MEMS in accordance with the invention will become apparent from the following detailed description and the descriptions of the drawings.

### BRIEF DESCRIPTION OF THE DRAWINGS

Many aspects of the present MEMS can be better understood with reference to the following drawings. The components in the drawings are not necessarily drawn to scale, the emphasis instead being placed upon clearly illustrating the principles of the present MEMS actuator assembly.

FIG. 1 is a partial cross sectional view of a MEMS in accordance with a first embodiment.

FIG. 2 is a partial cross sectional view of a MEMS in accordance with a second embodiment.

### DETAILED DESCRIPTION OF THE EXEMPLARY EMBODIMENTS

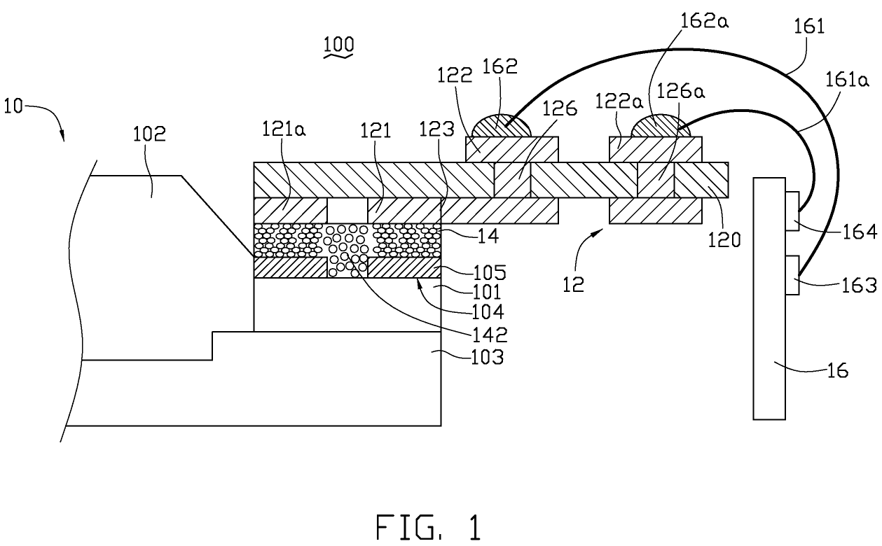

Referring to FIG. 1, a MEMS 100 in accordance with a first embodiment includes a MEMS chip package 10, a printed circuit board (PCB) 12, an anisotropic conductive layer 14, and a second PCB 16.

The MEMS chip package 10 includes a substrate 101, a top cover 102 and a bottom cover 103. The substrate 101 is packaged between the top cover 102 and the bottom cover 103. In other words, the top cover 102 and the bottom cover 103 surround and contact the substrate 101. The substrate 101 defines an exposed connecting portion 104 arranged at a corner thereof. The top cover 102 does not cover the exposed connecting portion 104, that is, the exposed connecting portion 104 is exposed from the MEMS chip package 10. Two metallic pads (e.g. aluminum pads) 105 are formed on the exposed connecting portion 104. It is to understood that amount of the metallic pads 105 can be varied according to practical demand.

The PCB 12 includes an insulating layer 120, two first connecting metallic pads 121, 121a, and two second connecting metallic pads 122, 122a. The first connecting metallic pads 121, 121a and the second connecting metallic pads 122, 122a are respectively formed on two opposite surfaces of the insulating layer 120. However, it is to be understood that the first connecting metallic pads 121, 121a and the second connecting metallic pads 122, 122a can also be formed on same surface of the insulating layer 120. The first connecting pad 121 and the second connecting pad 122 are electrically connected to each other with a conductive trace 123 and a conductive through hole 126. The first connecting pad 121a and the second connecting pad 122a can be also electrically connected with a conductive trace (not shown) and a conductive through hole 126a. The conductive through holes 126, 126a are filled with electrically conductive pastes such as copper pastes and silver pastes. The first PCB 12 can be flexible PCB or rigid PCB.

The anisotropic conductive layer 14 can be made of anisotropic conductive paste (ACP) or anisotropic conductive film (ACF). There are a number of contact balls 142 uniformly distributed in the anisotropic conductive layer 14. Each of the contact balls 142 includes an electrically conductive core and an insulating layer formed on an outer surface of the electrically conductive core. There are microstructures (i.e. small sharp protrusions) distributed on the outer surface of the electrically conductive core. Thus, when a pressure is applied onto the contact balls 142 the microstructures will pierce the insulating layer. As such, when the anisotropic conductive layer 14 is assembled between the aluminum pads 105 and the first connecting metallic pads 121, 121a, the two protruded aluminum pads 105 press the anisotropic conductive layer 14 such that the contact balls 142 above the aluminum pads 105 connect together. In addition, the microstructures pierce the insulating layer on the surfaces of the contact balls 142; as a result, the contact balls 142 are electrically conducted between each other, and each of the aluminum pads 105 is electrically conducted to a respective first connecting metallic pads. A distance between the two aluminum pads 105 is greater than a diameter of the contact balls; thus, a contact ball 142 can't electrically connect the two aluminum pads 105 itself.

The second PCB 16 is used to mounting a driving circuit for the MEMS chip package 10. In the first embodiment, two solder pads 163, 164 are formed on the second PCB 16. The second connecting metallic pad 122 is electrically connected to the solder pad 163 using a tiny electrical wire (e.g. a tiny copper wire) 161, and the second connecting metallic pad 122a is electrically connected to the solder pad 164 using a tiny wire (e.g. a tiny copper wire) 161a. The tiny electrical wires 161, 161a can be respectively bonded to the second connecting metallic pads 122, 122a by two solder balls 162, 162a. To reduce a volume of the MEMS 100, the second PCB 16 can be perpendicular to a plane that the MEMS chip package 10 lies in. Generally, the first PCB 12 is parallel to the plane; thus, the second PCB 16 is perpendicular to the first PCB 12. However, it is to be understood that the first PCB 12 can also bend at a certain angle when the first PCB 12 is a flexible PCB. In this instance, the first PCB 12 and the second PCB 16 is at an angle between each other.

During assembling of the MEMS assembly 100, firstly, the MEMS actuator 10, the PCB 12, and the anisotropic conductive layer 14 are provided. Secondly, the anisotropic conductive layer 14 is applied on the PCB 12 so as to cover the first connecting metallic pads 121, 121a. Lastly, the PCB 12 is laminated on the MEMS actuator 10. The anisotropic conductive layer 14 is sandwiched/interposed between the exposed connecting portion 104 of the MEMS actuator 10 and the PCB 12. During laminating of the PCB 12 and the MEMS actuator 10, a hot bar can be employed to apply force and heat on the PCB 12. The hot bar is structured to coincide with the PCB 12 and the exposed connecting portion 104.

In the present MEMS 100, the aluminum pads 105 of the MEMS actuator 10 are electrically connected to the first connecting metallic pads 121, 121a in the PCB 12, and the first connecting metallic pads 121, 121a are respectively connected to the second connecting metallic pads 122, 122a. Thus, when tiny copper wires are bonded with the second connecting metallic pads 122, 122a, the tiny copper wires are electrically connected to the aluminum pads 105 in the MEMS actuator 100. It is convenient to bond the tiny copper wires to the second connecting metallic pads 122, 122a. As a result, an electrical connection between the MEMS actuator 10 and a driver circuit (not shown) can be easily established.

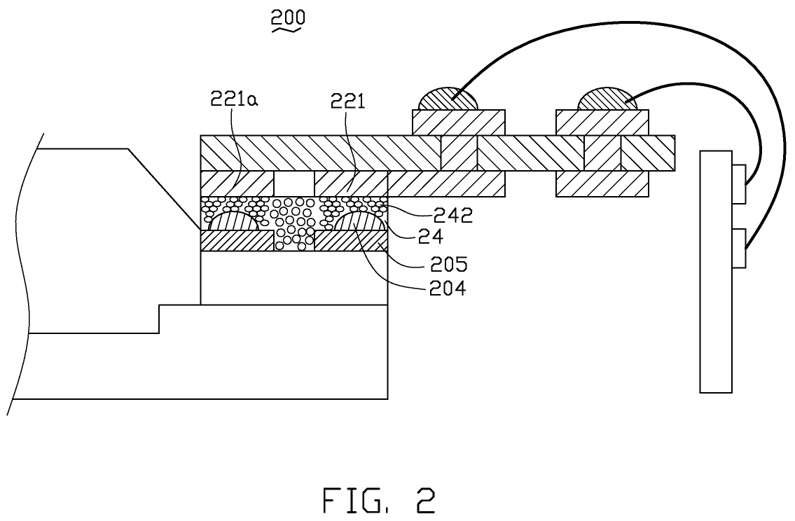

Referring to FIG. 2, a MEMS assembly 200 in accordance with a second embodiment is similar to the MEMS assembly 100 of the first embodiment except that a stud bump 204 is formed on each of the two aluminum pads 205. The stud bumps 204 can be made of high electrically conductive metals (e.g. gold, silver or copper). A typical used stud bump process in the art can be employed to form the stud bumps 204. The stud bumps 204 are in semi-sphere shape. However, it is to be understood that the stud bumps 204 can also be made into other shapes, for example, semi-ellipsoid, truncated cone, cuboid, etc.

In the present embodiment, the first connecting metallic pads 221, 221a are electrically connected to the aluminum pads 205 via a corresponding pair of a stud bump 206 and a pressed conductive ball 242a. In this instance, the diameter of the conductive balls 242a can be made far less than the thickness of the anisotropic conductive layer 24, accordingly, the distance between the two aluminum pads 205 can be further reduced. In other words, an area of the exposed connecting portion 204 can be further decreased, that is, a volume of the MEMS actuator can also be further decreased, and a more compact MEMS actuator can be employed.

Compared with the conventional MEMS actuator, the present MEMS employs an anisotropic conductive layer for electrically connecting the aluminum pads in the MEMS actuator to the PCB, and tiny copper wires can be easily bonded on the PCB. Thus, a reduced package volume of the MEMS actuator can be achieved.

Finally, it is to be understood that the above-described embodiments are intended to illustrate rather than limit the invention. Variations may be made to the embodiments without departing from the spirit of the invention as claimed. The above-described embodiments illustrate the scope of the invention but do not restrict the scope of the invention.

What is claimed is:

1. A MEMS, comprising:
a MEMS chip package, a first printed circuit board (PCB), an anisotropic conductive layer, a second PCB and at least one electrical wires,
the MEMS chip package comprising an exposed connecting portion, and at least one metallic pad formed on the exposed connecting portion;
the first PCB being laminated on the connecting portion, the first PCB comprising at least one first connecting metallic pad and at least one second connecting metallic pad, the first connecting metallic pad being electrically connected to a corresponding second connecting metallic pad;
the anisotropic conductive layer being sandwiched between the metallic pads of the MEMS chip package and the first connecting metallic pads of the first PCB, the metallic pad of the MEMS chip package being electrically connected to the respective first connecting metallic pad of the PCB via the anisotropic conductive layer;
one end of each electrical wire being bonded to a respective second connecting metallic pad and the other end being bonded to the second PCB.

2. The MEMS as claimed in claim 1, wherein two metallic pads formed on the exposed connecting portion, and the first PCB comprises two first connecting metallic pads and two second connecting metallic pads, each of the first connecting metallic pads being electrically connected to a corresponding second connecting metallic pad; the anisotropic conductive layer electrically connecting each of the metallic pads to a corresponding first connecting metallic pad.

3. The MEMS as claimed in claim 1, wherein the anisotropic conductive layer comprises a polymer matrix and a plurality of contact balls dispersed therein, each of the contact balls comprising an electrically conductive core and an insulating layer formed on an outer surface of the electrically conductive core, a plurality of microstructures being formed on the outer surface, the microstructures being configured for piercing the insulating layer such that adjacent contact balls are electrically connected.

4. The MEMS as claimed in claim 1, wherein the first connecting metallic pads are electrically connected to the respective second connecting metallic pads via a conductive hole.

5. The MEMS as claimed in claim 6, wherein a metallic bump is formed on each of the two metallic pads of the MEMS actuator, the anisotropic conductive layer electrically connecting the metallic bumps to the respective first connecting metallic pads.

6. The MEMS as claimed in claim 1, wherein the electrical wire are bonded to the second connecting metallic pad using a solder ball.

7. The MEMS as claimed in claim 1, wherein a driving circuit for the MEMS chip package is mounted on the second PCB.

8. The MEMS as claimed in claim 1, wherein the first PCB is a flexible PCB.

9. The MEMS as claimed in claim 1, wherein the second PCB is perpendicular to the first PCB.

10. The MEMS as claimed in claim 1, wherein the second PCB is perpendicular to a plane that the MEMS package lies in.
